(19) United States
(12) Patent Application Publication
(10) Pub. No.: US 2026/0211015 A1
(43) Pub. Date: Jul. 23, 2026

(54) UTILITY METER WITH ENHANCED CURRENT AND VOLTAGE MEASUREMENT AND PROCESSING

(71) Applicant: EI Electronics, LLC, d/b/a Electro Industries/Gauge Tech, Westbury, NY (US)

(72) Inventors: Tibor Banhegyesi, Northport, NY (US); Jorge Arturo Polar Seminario, Winter Garden, FL (US)

(21) Appl. No.: 19/456,476

(22) Filed: Jan. 22, 2026

Related U.S. Application Data
(60) Provisional application No. 63/748,596, filed on Jan. 23, 2025.

(51) Int. Cl. G01R 22/10; G01R 15/18

(52) U.S. Cl. CPC G01R 22/10; G01R 15/18

(57) ABSTRACT

A voltage/current meter apparatus with enhanced current and voltage measurement and processing includes one or more current transformers to sense current passing through a wire, a transimpedance amplifier connected to the current transformers, a single power rail configured to provide a middle voltage point as a reference for analog signals, a conductive pipe crimped to a primary side lead and configured for primary side current measurement, logic configured to detect sample differentiation between each of the three voltage phases Va, Vb and Vc and the reference voltage Vn, an internal analog-to-digital converter of a processor configured to convert the analog signals coming from the exterior, oversampling logic configured to converting a plurality of samples from the analog signal and provide an average result, and offset/linearization logic configured to provide a correction factor for a sample of the analog signal based on a previous calibration result.

### CROSS-REFERENCE TO RELATED APPLICATIONS

The present application claims priority from, and incorporates herein by reference in its entirety, U.S. provisional patent application 63/748,596 filed Jan. 23, 2025.

### FIELD

The present disclosure relates to electronic test and measurement devices. More particularly, the present disclosure relates to an improved meter for measuring voltage and current.

### BACKGROUND

Measurement and monitoring of electrical energy by consumers and providers of electric power is a fundamental function within any electric power distribution system. Electrical energy may be measured or monitored for purposes of usage, equipment performance and power quality. Electrical parameters that may be measured or monitored include volts, amps, watts, vars, power factor, harmonics, kilowatt hours, kilovar hours and any other power related measurement parameters. Typically, measurement of the voltage and current at a location within the electric power distribution system may be used to determine the electrical parameters for electrical energy flowing through that location.

Devices that perform measurement and monitoring of electrical energy may be electromechanical devices, such as, for example, a voltage or current meter, a residential billing meter or may be an intelligent electronic device (“IED”). Such electronic devices often include some form of a processor. In general, the processor is capable of using the measured voltage and current to derive the measurement parameters. The processor operates based on a software configuration. A typical consumer or supplier of electrical energy may have many intelligent electronic devices installed and operating throughout their operations. IEDs may be positioned along the supplier's distribution path or within a customer's internal distribution system. IEDs include revenue electric watt-hour meters, protection relays, programmable logic controllers, remote terminal units, fault recorders and other devices used to monitor and/or control electrical power distribution and consumption. IEDs are widely available that make use of memory and microprocessors to provide increased versatility and additional functionality. Such functionality includes the ability to communicate with remote computing systems, either via a direct connection, e.g., a modem, a wireless connection or a network. IEDs also include legacy mechanical or electromechanical devices that have been retrofitted with appropriate hardware and/or software allowing integration with the power management system.

Typically, an IED is associated with a particular load or set of loads that are drawing electrical power from the power distribution system. The IED may also be capable of receiving data from or controlling its associated load. Depending on the type of IED and the type of load it may be associated with, the IED implements a power management function that is able to respond to a power management command and/or generate power management data. Power management functions include measuring power consumption, controlling power distribution such as a relay function, monitoring power quality, measuring power parameters such as phasor components, voltage or current, controlling power generation facilities, computing revenue, controlling electrical power flow and load shedding, or combinations thereof.

Conventional IEDs include the ability to communicate with remote computing systems. Traditionally, IEDs would transfer data using serial-based download commands. These commands would be accessed via an RS232, and RS485 or an Ethernet port encapsulating the serial request with an Ethernet message using any Ethernet protocol such as HTTP or TCP/IP. For instance, host software or a “master” would make a request for a set of data from one or more memory registers in an IED slave. At that point, the IED slave would then communicate the data stored in the memory registers back to the host software utilizing a serial transfer. A need exists for systems and methods for efficiently collecting data from various devices, e.g., IEDs. A further need exists for systems and methods for analyzing and reporting such collected data.

### SUMMARY

In certain implementations a utility meter includes enhanced current and voltage measurement that can enhance the accuracy of voltage and current readings.

In certain implementations a utility meter includes one or more current transformers to sense current passing through a wire, sampling circuitry that detects the current passing through the wire and provides a current sample, a transimpedance amplifier connected to the current transformers, and a middle reference terminal electrically connected to the transimpedance amplifier. The transimpedance amplifier may be configured as part of the sampling circuitry.

In some forms, the utility meter includes a single power rail configured to provide a middle voltage point as a reference for analog signals.

In some forms, the utility meter includes a conductive pipe crimped to a primary side lead and configured for primary side current measurement. The conductive pipe may be made from copper.

In some forms, the utility meter may include a voltage phase reference terminal having a phase reference Vn. In some forms, the utility meter includes logic configured to detect sample differentiation between each of the three voltage phases Va, Vb and Vc and the reference voltage Vn.

In some forms, the utility meter includes logic configured to detect sample differentiation between the voltage Va and the phase reference Vn, between the voltage phase Vb and the phase reference Vn, and between the voltage phase Vc and the phase reference Vn.

In some forms, the utility meter includes an internal analog-to-digital converter of a processor configured to convert the analog signals coming from the exterior.

In some forms, the utility meter includes oversampling logic configured to convert a plurality of samples from an analog signal and provide an average result. In some forms, the utility meter includes offset/linearization logic configured to provide a correction factor for a sample of the analog signal based on a previous calibration result.

In some forms, the utility meter includes offset/linearization logic configured to provide a correction factor for a sample of the analog signal based on a previous calibration result.

An electronic power meter can include a plurality of sensors configured to sense electrical parameters on a plurality of phases of an electrical power system. The electronic power meter can include at least one analog-to-digital converter configured to convert analog signals into digital data. The electronic power meter can include a processing system operatively coupled to the at least one analog-to-digital converter and configured to process the digital data. The electronic power meter can include a memory unit operatively coupled to the processing system. The electronic power meter can include a current measurement front end coupled between the plurality of sensors and the at least one analog-to-digital converter. The current measurement front end can include at least one current transformer configured to generate a current sample proportional to a current flowing in a conductor of the electrical power system. The current measurement front end can include offset circuitry electrically coupled to a secondary winding of the at least one current transformer and configured to bias terminals of the secondary winding to a reference voltage. The current measurement front end can include a transimpedance amplifier electrically coupled to the secondary winding and to the offset circuitry. The transimpedance amplifier can be configured to convert the current sample into a voltage signal for input to the at least one analog-to-digital converter.

The offset circuitry can include at least one diode pair connected across the secondary winding of the at least one current transformer and configured to limit a voltage across the secondary winding. The transimpedance amplifier can include an operational amplifier having a feedback resistor connected between an output terminal and an inverting input terminal and having a non-inverting input terminal biased to the reference voltage. The transimpedance amplifier can further include a feedback capacitor connected in parallel with the feedback resistor and configured to set a frequency response of the current measurement front end. The current measurement front end can include a plurality of current transformers respectively associated with a plurality of phases of the electrical power system and a plurality of transimpedance amplifiers respectively associated with the plurality of current transformers. The offset circuitry can be configured to maintain a voltage at the terminals of the secondary winding of the at least one current transformer within a predetermined range to reduce phase shift and loading of the at least one current transformer.

A method of measuring current in an electronic power meter can include sensing, by at least one current transformer, a current flowing in a conductor of an electrical power system and generating a current sample proportional to the current. The method can include biasing, by offset circuitry, terminals of a secondary winding of the at least one current transformer to a reference voltage. The method can include converting, by a transimpedance amplifier electrically coupled to the secondary winding, the current sample into a voltage signal. The method can include converting, by at least one analog-to-digital converter, the voltage signal into digital data. The method can include processing, by a processing system, the digital data to determine at least one current-related parameter of the electrical power system.

Biasing the terminals of the secondary winding can include clamping a voltage across the secondary winding using at least one diode pair connected across the secondary winding. Converting the current sample into the voltage signal can include applying the current sample to an inverting input of an operational amplifier having a feedback resistor and biasing a non-inverting input of the operational amplifier to the reference voltage. The method can further include filtering the voltage signal using a feedback capacitor connected in parallel with a feedback resistor of the transimpedance amplifier. Sensing the current can include sensing a plurality of phase currents of the electrical power system using a corresponding plurality of current transformers and converting a plurality of current samples into a plurality of voltage signals using a corresponding plurality of transimpedance amplifiers. Biasing the terminals of the secondary winding can include maintaining a voltage across the secondary winding of the at least one current transformer below a threshold to reduce phase shift of the current transformer.

An electronic power meter can include a plurality of sensors configured to sense electrical parameters on a plurality of phases of an electrical power system. The electronic power meter can include at least one analog-to-digital converter configured to convert analog signals into digital data. The electronic power meter can include a processing system operatively coupled to the at least one analog-to-digital converter and configured to process the digital data. The electronic power meter can include a power supply configured to provide a single power rail having a supply voltage referenced to a ground node. The electronic power meter can include analog measurement circuitry coupled between the plurality of sensors and the at least one analog-to-digital converter. The analog measurement circuitry can include a middle voltage reference circuit configured to generate a middle voltage point between the supply voltage and the ground node. The analog measurement circuitry can include one or more analog front-end amplifiers powered from the single power rail and referenced to the middle voltage point and configured to generate one or more analog measurement signals for input to the at least one analog-to-digital converter.

The middle voltage reference circuit can include at least one operational amplifier configured as a buffer for the middle voltage point. The middle voltage reference circuit can include a resistor network configured to divide the supply voltage and provide an intermediate voltage to an input of an operational amplifier. The middle voltage reference circuit can include at least one decoupling capacitor configured to reduce noise on the middle voltage point. The one or more analog front-end amplifiers can include at least one transimpedance amplifier configured to convert a current signal from at least one current transformer into a voltage signal referenced to the middle voltage point. The one or more analog front-end amplifiers can include at least one voltage-sensing amplifier configured to condition a voltage signal derived from a phase of the electrical power system with reference to the middle voltage point.

A method of operating an analog front end of an electronic power meter can include providing, by a power supply, a single power rail having a supply voltage referenced to a ground node. The method can include generating, by a middle voltage reference circuit, a middle voltage point between the supply voltage and the ground node. The method can include powering one or more analog front-end amplifiers from the single power rail. The method can include referencing the one or more analog front-end amplifiers to the middle voltage point. The method can include receiving, at the one or more analog front-end amplifiers, one or more sensor signals from a plurality of sensors coupled to an electrical power system. The method can include generating, by the one or more analog front-end amplifiers, one or more analog measurement signals referenced to the middle voltage point. The method can include converting, by at least one analog-to-digital converter, the one or more analog measurement signals into digital data for processing by a processing system.

Generating the middle voltage point can include dividing the supply voltage using a resistor network and buffering the divided voltage using an operational amplifier. The method can further include filtering noise on the middle voltage point using at least one decoupling capacitor. Receiving the one or more sensor signals can include receiving a current signal from at least one current transformer and generating a corresponding voltage signal referenced to the middle voltage point using a transimpedance amplifier. Receiving the one or more sensor signals can include receiving a voltage signal derived from a phase of the electrical power system and conditioning the voltage signal using an amplifier referenced to the middle voltage point. The method can further include maintaining the middle voltage point within a predetermined tolerance relative to one-half of the supply voltage.

An electronic power meter can include a plurality of sensors configured to sense electrical parameters on a plurality of phases of an electrical power system. The electronic power meter can include at least one analog-to-digital converter configured to convert analog signals into digital data. The electronic power meter can include a processing system operatively coupled to the at least one analog-to-digital converter and configured to process the digital data. The electronic power meter can include a voltage measurement front end coupled between the plurality of sensors and the at least one analog-to-digital converter. The voltage measurement front end can include a plurality of phase voltage inputs configured to receive respective phase voltages Va, Vb, and Vc of the electrical power system. The voltage measurement front end can include a reference voltage input configured to receive a reference voltage Vn associated with the electrical power system. The voltage measurement front end can include voltage sensing circuitry configured to provide to the at least one analog-to-digital converter analog signals corresponding to the phase voltages Va, Vb, Vc and the reference voltage Vn. The processing system can be configured to determine phase-differential voltages based on differences between digital samples representative of a respective one of the phase voltages and digital samples representative of the reference voltage Vn.

The at least one analog-to-digital converter can include a first analog-to-digital converter channel configured to convert the phase voltage Va and a second analog-to-digital converter channel configured to convert the reference voltage Vn substantially simultaneously. The processing system can be configured to compute a first phase-differential voltage based on a difference between samples of Va and Vn, a second phase-differential voltage based on a difference between samples of Vb and Vn, and a third phase-differential voltage based on a difference between samples of Vc and Vn. The voltage sensing circuitry can include scaling and protection components configured to scale the phase voltages Va, Vb, Vc and the reference voltage Vn to input ranges of the at least one analog-to-digital converter. The processing system can be configured to compute at least one power quantity based on the phase-differential voltages. The at least one analog-to-digital converter can include at least two analog-to-digital converters configured to sample at least one of the phase voltages and the reference voltage Vn simultaneously.

A method of measuring voltages in an electronic power meter can include receiving, at a plurality of phase voltage inputs, phase voltages Va, Vb, and Vc of an electrical power system. The method can include receiving, at a reference voltage input, a reference voltage Vn associated with the electrical power system. The method can include generating, by voltage sensing circuitry, analog signals corresponding to the phase voltages Va, Vb, Vc and the reference voltage Vn. The method can include converting, by at least one analog-to-digital converter, the analog signals corresponding to the phase voltages Va, Vb, Vc and the reference voltage Vn into digital samples. The method can include determining, by a processing system, one or more phase-differential voltages based on differences between digital samples representative of the phase voltages Va, Vb, Vc and digital samples representative of the reference voltage Vn.

Converting the analog signals can include substantially simultaneously sampling a selected one of the phase voltages and the reference voltage Vn using at least two analog-to-digital converter channels. Determining the one or more phase-differential voltages can include computing Va-Vn, Vb-Vn, and Vc-Vn on a sample-by-sample basis. The method can further include scaling the phase voltages Va, Vb, Vc and the reference voltage Vn to respective input ranges of the at least one analog-to-digital converter prior to converting. The method can further include computing at least one power-related parameter based on the one or more phase-differential voltages. The method can further include time-aligning the digital samples representative of the phase voltages Va, Vb, Vc and the reference voltage Vn prior to determining the one or more phase-differential voltages.

An electronic power meter can include a plurality of sensors configured to sense electrical parameters on a plurality of phases of an electrical power system. The electronic power meter can include analog front-end circuitry configured to generate one or more analog measurement signals from outputs of the plurality of sensors. The electronic power meter can include a processing system including at least one internal analog-to-digital converter configured to convert the one or more analog measurement signals into digital samples. The electronic power meter can include a memory unit operatively coupled to the processing system and configured to store calibration data. The processing system can be configured to control the at least one internal analog-to-digital converter to obtain a plurality of digital samples for a given analog measurement signal. The processing system can be configured to generate an oversampled result based on the plurality of digital samples. The processing system can be configured to apply a correction factor based on the calibration data to the oversampled result to provide a corrected measurement value.

The plurality of digital samples can include eight digital samples obtained for the given analog measurement signal. The oversampled result can include an average of the plurality of digital samples. The calibration data can include at least one offset value and at least one linearization parameter associated with the at least one internal analog-to-digital converter. The at least one internal analog-to-digital converter can be integrated within a microcontroller of the processing system and can be used in place of an external metering analog-to-digital converter. The processing system can be configured to associate respective calibration data with a plurality of analog measurement channels and to apply channel-specific correction factors to corresponding oversampled results.

A method of measuring electrical parameters using an electronic power meter can include generating, by analog front-end circuitry, at least one analog measurement signal from an output of at least one sensor configured to sense an electrical parameter of an electrical power system. The method can include converting, by at least one internal analog-to-digital converter of a processing system, the at least one analog measurement signal into a plurality of digital samples. The method can include generating, by the processing system, an oversampled result based on the plurality of digital samples. The method can include obtaining, by the processing system, calibration data associated with the at least one internal analog-to-digital converter. The method can include applying, by the processing system, a correction factor based on the calibration data to the oversampled result to provide a corrected measurement value.

Converting the at least one analog measurement signal into the plurality of digital samples can include generating eight digital samples for the at least one analog measurement signal. Generating the oversampled result can include averaging the plurality of digital samples. The calibration data can include at least one offset value and at least one linearization parameter associated with the at least one internal analog-to-digital converter, and applying the correction factor can include adjusting the oversampled result based on the offset value and the linearization parameter. The method can further include storing the calibration data in a memory unit operatively coupled to the processing system. The method can further include computing at least one power-related quantity of the electrical power system based on the corrected measurement value.

An electronic power meter can include a plurality of sensors configured to sense electrical parameters on a plurality of phases of an electrical power system. The electronic power meter can include analog front-end circuitry coupled to the plurality of sensors and configured to generate analog measurement signals representative of currents and voltages of the electrical power system. The electronic power meter can include a processing system including at least one internal analog-to-digital converter configured to convert the analog measurement signals into digital samples. The analog front-end circuitry can include a current measurement front end comprising, for at least one phase, a current transformer configured to generate a current sample proportional to a current flowing in a conductor of the electrical power system, offset circuitry electrically coupled to a secondary winding of the current transformer and configured to bias terminals of the secondary winding to a middle voltage point, and a transimpedance amplifier powered from the single power rail and referenced to the middle voltage point and configured to convert the current sample into a current-related voltage signal. The analog front-end circuitry can include a voltage measurement front end comprising a plurality of phase voltage inputs configured to receive respective phase voltages Va, Vb, and Vc of the electrical power system, a reference voltage input configured to receive a reference voltage Vn associated with the electrical power system, and voltage sensing circuitry configured to generate analog voltage signals corresponding to the phase voltages Va, Vb, Vc and the reference voltage Vn. The analog front-end circuitry can include a middle voltage reference circuit powered from the single power rail and configured to generate the middle voltage point between the supply voltage and the ground node. The processing system can be configured to control the at least one internal analog-to-digital converter to obtain digital samples of the current-related voltage signal and the analog voltage signals corresponding to Va, Vb, Vc, and Vn. The processing system can be configured to obtain, for each of a plurality of measurement intervals, a plurality of digital samples for at least one of the current-related voltage signal and the analog voltage signals. The processing system can be configured to generate, for each of the plurality of measurement intervals, at least one oversampled result based on the plurality of digital samples. The processing system can be configured to determine phase-differential voltages based on differences between digital samples representative of the phase voltages Va, Vb, Vc and digital samples representative of the reference voltage Vn. The processing system can be configured to apply at least one correction factor based on calibration data stored in the memory unit to the at least one oversampled result to provide a corrected measurement value for use in computing at least one power-related quantity.

The offset circuitry can include at least one diode pair connected across the secondary winding of the current transformer and configured to limit a voltage across the secondary winding. The transimpedance amplifier can include an operational amplifier having a feedback resistor connected between an output terminal and an inverting input terminal and having a non-inverting input terminal biased to the middle voltage point. The at least one internal analog-to-digital converter can be integrated within a microcontroller of the processing system and can be configured to perform simultaneous sampling of at least one of the phase voltages and the reference voltage Vn. Generating the at least one oversampled result can include averaging eight digital samples obtained for a given analog measurement signal during a corresponding one of the plurality of measurement intervals. The calibration data can include at least one offset value and at least one linearization parameter associated with the at least one internal analog-to-digital converter, and applying the at least one correction factor can include adjusting the at least one oversampled result based on the at least one offset value and the at least one linearization parameter.

A method of measuring electrical parameters using an electronic power meter can include providing, by a power supply, a single power rail having a supply voltage referenced to a ground node. The method can include generating, by a middle voltage reference circuit powered from the single power rail, a middle voltage point between the supply voltage and the ground node. The method can include sensing, by at least one current transformer, a current flowing in a conductor of an electrical power system and generating a current sample proportional to the current. The method can include biasing, by offset circuitry electrically coupled to a secondary winding of the at least one current transformer, terminals of the secondary winding to the middle voltage point. The method can include converting, by a transimpedance amplifier powered from the single power rail and referenced to the middle voltage point, the current sample into a current-related voltage signal. The method can include receiving, at a plurality of phase voltage inputs, phase voltages Va, Vb, and Vc of the electrical power system and receiving, at a reference voltage input, a reference voltage Vn associated with the electrical power system. The method can include generating, by voltage sensing circuitry, analog voltage signals corresponding to the phase voltages Va, Vb, Vc and the reference voltage Vn. The method can include converting, by at least one internal analog-to-digital converter of a processing system, the current-related voltage signal and the analog voltage signals into digital samples. The method can include obtaining, by the processing system, for each of a plurality of measurement intervals, a plurality of digital samples for at least one of the current-related voltage signal and the analog voltage signals. The method can include generating, by the processing system, at least one oversampled result for each of the plurality of measurement intervals based on the plurality of digital samples. The method can include determining, by the processing system, phase-differential voltages based on differences between digital samples representative of the phase voltages Va, Vb, Vc and digital samples representative of the reference voltage Vn. The method can include obtaining, by the processing system, calibration data associated with the at least one internal analog-to-digital converter. The method can include applying, by the processing system, at least one correction factor based on the calibration data to the at least one oversampled result to provide at least one corrected measurement value. The method can include computing, by the processing system, at least one power-related quantity of the electrical power system based on the at least one corrected measurement value and the phase-differential voltages.

Converting the current-related voltage signal and the analog voltage signals into digital samples can include substantially simultaneously sampling a selected one of the phase voltages and the reference voltage Vn using the at least one internal analog-to-digital converter. Generating the at least one oversampled result can include averaging eight digital samples obtained for a given analog measurement signal during a corresponding one of the plurality of measurement intervals. The calibration data can include at least one offset value and at least one linearization parameter associated with the at least one internal analog-to-digital converter, and applying the at least one correction factor can include adjusting the at least one oversampled result based on the at least one offset value and the at least one linearization parameter. The method can further include clamping a voltage across the secondary winding of the at least one current transformer using at least one diode pair connected across the secondary winding. The method can further include time-aligning the digital samples representative of the phase voltages Va, Vb, Vc and the reference voltage Vn prior to determining the phase-differential voltages.

An electronic power meter can include a plurality of sensors configured to sense electrical parameters on a plurality of phases of an electrical power system. The electronic power meter can include at least one analog-to-digital converter configured to convert analog signals into digital data. The electronic power meter can include a processing system operatively coupled to the at least one analog-to-digital converter and configured to process the digital data. The electronic power meter can include a memory unit operatively coupled to the processing system. The electronic power meter can include a current measurement front end coupled between the plurality of sensors and the at least one analog-to-digital converter. The current measurement front end can include at least one current transformer configured to generate a current sample proportional to a current flowing in a conductor of the electrical power system. The current measurement front end can include offset circuitry electrically coupled to a secondary winding of the at least one current transformer and configured to bias terminals of the secondary winding to a reference voltage. The current measurement front end can include a transimpedance amplifier electrically coupled to the secondary winding and to the offset circuitry. The transimpedance amplifier can be configured to convert the current sample into a voltage signal for input to the at least one analog-to-digital converter.

The offset circuitry can include at least one diode pair connected across the secondary winding of the at least one current transformer and configured to limit a voltage across the secondary winding. The transimpedance amplifier can include an operational amplifier having a feedback resistor connected between an output terminal and an inverting input terminal and having a non-inverting input terminal biased to the reference voltage. The transimpedance amplifier can further include a feedback capacitor connected in parallel with the feedback resistor and configured to set a frequency response of the current measurement front end. The current measurement front end can include a plurality of current transformers respectively associated with a plurality of phases of the electrical power system and a plurality of transimpedance amplifiers respectively associated with the plurality of current transformers. The offset circuitry can be configured to maintain a voltage at the terminals of the secondary winding of the at least one current transformer within a predetermined range to reduce phase shift and loading of the at least one current transformer.

A method of measuring current in an electronic power meter can include sensing, by at least one current transformer, a current flowing in a conductor of an electrical power system and generating a current sample proportional to the current. The method can include biasing, by offset circuitry, terminals of a secondary winding of the at least one current transformer to a reference voltage. The method can include converting, by a transimpedance amplifier electrically coupled to the secondary winding, the current sample into a voltage signal. The method can include converting, by at least one analog-to-digital converter, the voltage signal into digital data. The method can include processing, by a processing system, the digital data to determine at least one current-related parameter of the electrical power system.

Biasing the terminals of the secondary winding can include clamping a voltage across the secondary winding using at least one diode pair connected across the secondary winding. Converting the current sample into the voltage signal can include applying the current sample to an inverting input of an operational amplifier having a feedback resistor and biasing a non-inverting input of the operational amplifier to the reference voltage. The method can further include filtering the voltage signal using a feedback capacitor connected in parallel with a feedback resistor of the transimpedance amplifier. Sensing the current can include sensing a plurality of phase currents of the electrical power system using a corresponding plurality of current transformers and converting a plurality of current samples into a plurality of voltage signals using a corresponding plurality of transimpedance amplifiers. Biasing the terminals of the secondary winding can include maintaining a voltage across the secondary winding of the at least one current transformer below a threshold to reduce phase shift of the current transformer.

An electronic power meter can include a plurality of sensors configured to sense electrical parameters on a plurality of phases of an electrical power system. The electronic power meter can include at least one analog-to-digital converter configured to convert analog signals into digital data. The electronic power meter can include a processing system operatively coupled to the at least one analog-to-digital converter and configured to process the digital data. The electronic power meter can include a power supply configured to provide a single power rail having a supply voltage referenced to a ground node. The electronic power meter can include analog measurement circuitry coupled between the plurality of sensors and the at least one analog-to-digital converter. The analog measurement circuitry can include a middle voltage reference circuit configured to generate a middle voltage point between the supply voltage and the ground node. The analog measurement circuitry can include one or more analog front-end amplifiers powered from the single power rail and referenced to the middle voltage point and configured to generate one or more analog measurement signals for input to the at least one analog-to-digital converter.

The middle voltage reference circuit can include at least one operational amplifier configured as a buffer for the middle voltage point. The middle voltage reference circuit can include a resistor network configured to divide the supply voltage and provide an intermediate voltage to an input of an operational amplifier. The middle voltage reference circuit can include at least one decoupling capacitor configured to reduce noise on the middle voltage point. The one or more analog front-end amplifiers can include at least one transimpedance amplifier configured to convert a current signal from at least one current transformer into a voltage signal referenced to the middle voltage point. The one or more analog front-end amplifiers can include at least one voltage-sensing amplifier configured to condition a voltage signal derived from a phase of the electrical power system with reference to the middle voltage point.

A method of operating an analog front end of an electronic power meter can include providing, by a power supply, a single power rail having a supply voltage referenced to a ground node. The method can include generating, by a middle voltage reference circuit, a middle voltage point between the supply voltage and the ground node. The method can include powering one or more analog front-end amplifiers from the single power rail. The method can include referencing the one or more analog front-end amplifiers to the middle voltage point. The method can include receiving, at the one or more analog front-end amplifiers, one or more sensor signals from a plurality of sensors coupled to an electrical power system. The method can include generating, by the one or more analog front-end amplifiers, one or more analog measurement signals referenced to the middle voltage point. The method can include converting, by at least one analog-to-digital converter, the one or more analog measurement signals into digital data for processing by a processing system.

Generating the middle voltage point can include dividing the supply voltage using a resistor network and buffering the divided voltage using an operational amplifier. The method can further include filtering noise on the middle voltage point using at least one decoupling capacitor. Receiving the one or more sensor signals can include receiving a current signal from at least one current transformer and generating a corresponding voltage signal referenced to the middle voltage point using a transimpedance amplifier. Receiving the one or more sensor signals can include receiving a voltage signal derived from a phase of the electrical power system and conditioning the voltage signal using an amplifier referenced to the middle voltage point. The method can further include maintaining the middle voltage point within a predetermined tolerance relative to one-half of the supply voltage.

An electronic power meter can include a plurality of sensors configured to sense electrical parameters on a plurality of phases of an electrical power system. The electronic power meter can include at least one analog-to-digital converter configured to convert analog signals into digital data. The electronic power meter can include a processing system operatively coupled to the at least one analog-to-digital converter and configured to process the digital data. The electronic power meter can include a voltage measurement front end coupled between the plurality of sensors and the at least one analog-to-digital converter. The voltage measurement front end can include a plurality of phase voltage inputs configured to receive respective phase voltages Va, Vb, and Vc of the electrical power system. The voltage measurement front end can include a reference voltage input configured to receive a reference voltage Vn associated with the electrical power system. The voltage measurement front end can include voltage sensing circuitry configured to provide to the at least one analog-to-digital converter analog signals corresponding to the phase voltages Va, Vb, Vc and the reference voltage Vn. The processing system can be configured to determine phase-differential voltages based on differences between digital samples representative of a respective one of the phase voltages and digital samples representative of the reference voltage Vn.

The at least one analog-to-digital converter can include a first analog-to-digital converter channel configured to convert the phase voltage Va and a second analog-to-digital converter channel configured to convert the reference voltage Vn substantially simultaneously. The processing system can be configured to compute a first phase-differential voltage based on a difference between samples of Va and Vn, a second phase-differential voltage based on a difference between samples of Vb and Vn, and a third phase-differential voltage based on a difference between samples of Vc and Vn. The voltage sensing circuitry can include scaling and protection components configured to scale the phase voltages Va, Vb, Vc and the reference voltage Vn to input ranges of the at least one analog-to-digital converter. The processing system can be configured to compute at least one power quantity based on the phase-differential voltages. The at least one analog-to-digital converter can include at least two analog-to-digital converters configured to sample at least one of the phase voltages and the reference voltage Vn simultaneously.

A method of measuring voltages in an electronic power meter can include receiving, at a plurality of phase voltage inputs, phase voltages Va, Vb, and Vc of an electrical power system. The method can include receiving, at a reference voltage input, a reference voltage Vn associated with the electrical power system. The method can include generating, by voltage sensing circuitry, analog signals corresponding to the phase voltages Va, Vb, Vc and the reference voltage Vn. The method can include converting, by at least one analog-to-digital converter, the analog signals corresponding to the phase voltages Va, Vb, Vc and the reference voltage Vn into digital samples. The method can include determining, by a processing system, one or more phase-differential voltages based on differences between digital samples representative of the phase voltages Va, Vb, Vc and digital samples representative of the reference voltage Vn.

Converting the analog signals can include substantially simultaneously sampling a selected one of the phase voltages and the reference voltage Vn using at least two analog-to-digital converter channels. Determining the one or more phase-differential voltages can include computing Va-Vn, Vb-Vn, and Vc-Vn on a sample-by-sample basis. The method can further include scaling the phase voltages Va, Vb, Vc and the reference voltage Vn to respective input ranges of the at least one analog-to-digital converter prior to converting. The method can further include computing at least one power-related parameter based on the one or more phase-differential voltages. The method can further include time-aligning the digital samples representative of the phase voltages Va, Vb, Vc and the reference voltage Vn prior to determining the one or more phase-differential voltages.

An electronic power meter can include a plurality of sensors configured to sense electrical parameters on a plurality of phases of an electrical power system. The electronic power meter can include analog front-end circuitry configured to generate one or more analog measurement signals from outputs of the plurality of sensors. The electronic power meter can include a processing system including at least one internal analog-to-digital converter configured to convert the one or more analog measurement signals into digital samples. The electronic power meter can include a memory unit operatively coupled to the processing system and configured to store calibration data. The processing system can be configured to control the at least one internal analog-to-digital converter to obtain a plurality of digital samples for a given analog measurement signal. The processing system can be configured to generate an oversampled result based on the plurality of digital samples. The processing system can be configured to apply a correction factor based on the calibration data to the oversampled result to provide a corrected measurement value.

The plurality of digital samples can include eight digital samples obtained for the given analog measurement signal. The oversampled result can include an average of the plurality of digital samples. The calibration data can include at least one offset value and at least one linearization parameter associated with the at least one internal analog-to-digital converter. The at least one internal analog-to-digital converter can be integrated within a microcontroller of the processing system and can be used in place of an external metering analog-to-digital converter. The processing system can be configured to associate respective calibration data with a plurality of analog measurement channels and to apply channel-specific correction factors to corresponding oversampled results.

A method of measuring electrical parameters using an electronic power meter can include generating, by analog front-end circuitry, at least one analog measurement signal from an output of at least one sensor configured to sense an electrical parameter of an electrical power system. The method can include converting, by at least one internal analog-to-digital converter of a processing system, the at least one analog measurement signal into a plurality of digital samples. The method can include generating, by the processing system, an oversampled result based on the plurality of digital samples. The method can include obtaining, by the processing system, calibration data associated with the at least one internal analog-to-digital converter. The method can include applying, by the processing system, a correction factor based on the calibration data to the oversampled result to provide a corrected measurement value.

Converting the at least one analog measurement signal into the plurality of digital samples can include generating eight digital samples for the at least one analog measurement signal. Generating the oversampled result can include averaging the plurality of digital samples. The calibration data can include at least one offset value and at least one linearization parameter associated with the at least one internal analog-to-digital converter, and applying the correction factor can include adjusting the oversampled result based on the offset value and the linearization parameter. The method can further include storing the calibration data in a memory unit operatively coupled to the processing system. The method can further include computing at least one power-related quantity of the electrical power system based on the corrected measurement value.

An electronic power meter can include a plurality of sensors configured to sense electrical parameters on a plurality of phases of an electrical power system. The electronic power meter can include analog front-end circuitry coupled to the plurality of sensors and configured to generate analog measurement signals representative of currents and voltages of the electrical power system. The electronic power meter can include a processing system including at least one internal analog-to-digital converter configured to convert the analog measurement signals into digital samples. The analog front-end circuitry can include a current measurement front end comprising, for at least one phase, a current transformer configured to generate a current sample proportional to a current flowing in a conductor of the electrical power system, offset circuitry electrically coupled to a secondary winding of the current transformer and configured to bias terminals of the secondary winding to a middle voltage point, and a transimpedance amplifier powered from the single power rail and referenced to the middle voltage point and configured to convert the current sample into a current-related voltage signal. The analog front-end circuitry can include a voltage measurement front end comprising a plurality of phase voltage inputs configured to receive respective phase voltages Va, Vb, and Vc of the electrical power system, a reference voltage input configured to receive a reference voltage Vn associated with the electrical power system, and voltage sensing circuitry configured to generate analog voltage signals corresponding to the phase voltages Va, Vb, Vc and the reference voltage Vn. The analog front-end circuitry can include a middle voltage reference circuit powered from the single power rail and configured to generate the middle voltage point between the supply voltage and the ground node. The processing system can be configured to control the at least one internal analog-to-digital converter to obtain digital samples of the current-related voltage signal and the analog voltage signals corresponding to Va, Vb, Vc, and Vn. The processing system can be configured to obtain, for each of a plurality of measurement intervals, a plurality of digital samples for at least one of the current-related voltage signal and the analog voltage signals. The processing system can be configured to generate, for each of the plurality of measurement intervals, at least one oversampled result based on the plurality of digital samples. The processing system can be configured to determine phase-differential voltages based on differences between digital samples representative of the phase voltages Va, Vb, Vc and digital samples representative of the reference voltage Vn. The processing system can be configured to apply at least one correction factor based on calibration data stored in the memory unit to the at least one oversampled result to provide a corrected measurement value for use in computing at least one power-related quantity.

The offset circuitry can include at least one diode pair connected across the secondary winding of the current transformer and configured to limit a voltage across the secondary winding. The transimpedance amplifier can include an operational amplifier having a feedback resistor connected between an output terminal and an inverting input terminal and having a non-inverting input terminal biased to the middle voltage point. The at least one internal analog-to-digital converter can be integrated within a microcontroller of the processing system and can be configured to perform simultaneous sampling of at least one of the phase voltages and the reference voltage Vn. Generating the at least one oversampled result can include averaging eight digital samples obtained for a given analog measurement signal during a corresponding one of the plurality of measurement intervals. The calibration data can include at least one offset value and at least one linearization parameter associated with the at least one internal analog-to-digital converter, and applying the at least one correction factor can include adjusting the at least one oversampled result based on the at least one offset value and the at least one linearization parameter.

A method of measuring electrical parameters using an electronic power meter can include providing, by a power supply, a single power rail having a supply voltage referenced to a ground node. The method can include generating, by a middle voltage reference circuit powered from the single power rail, a middle voltage point between the supply voltage and the ground node. The method can include sensing, by at least one current transformer, a current flowing in a conductor of an electrical power system and generating a current sample proportional to the current. The method can include biasing, by offset circuitry electrically coupled to a secondary winding of the at least one current transformer, terminals of the secondary winding to the middle voltage point. The method can include converting, by a transimpedance amplifier powered from the single power rail and referenced to the middle voltage point, the current sample into a current-related voltage signal. The method can include receiving, at a plurality of phase voltage inputs, phase voltages Va, Vb, and Vc of the electrical power system and receiving, at a reference voltage input, a reference voltage Vn associated with the electrical power system. The method can include generating, by voltage sensing circuitry, analog voltage signals corresponding to the phase voltages Va, Vb, Vc and the reference voltage Vn. The method can include converting, by at least one internal analog-to-digital converter of a processing system, the current-related voltage signal and the analog voltage signals into digital samples. The method can include obtaining, by the processing system, for each of a plurality of measurement intervals, a plurality of digital samples for at least one of the current-related voltage signal and the analog voltage signals. The method can include generating, by the processing system, at least one oversampled result for each of the plurality of measurement intervals based on the plurality of digital samples. The method can include determining, by the processing system, phase-differential voltages based on differences between digital samples representative of the phase voltages Va, Vb, Vc and digital samples representative of the reference voltage Vn. The method can include obtaining, by the processing system, calibration data associated with the at least one internal analog-to-digital converter. The method can include applying, by the processing system, at least one correction factor based on the calibration data to the at least one oversampled result to provide at least one corrected measurement value. The method can include computing, by the processing system, at least one power-related quantity of the electrical power system based on the at least one corrected measurement value and the phase-differential voltages.

Converting the current-related voltage signal and the analog voltage signals into digital samples can include substantially simultaneously sampling a selected one of the phase voltages and the reference voltage Vn using the at least one internal analog-to-digital converter. Generating the at least one oversampled result can include averaging eight digital samples obtained for a given analog measurement signal during a corresponding one of the plurality of measurement intervals. The calibration data can include at least one offset value and at least one linearization parameter associated with the at least one internal analog-to-digital converter, and applying the at least one correction factor can include adjusting the at least one oversampled result based on the at least one offset value and the at least one linearization parameter. The method can further include clamping a voltage across the secondary winding of the at least one current transformer using at least one diode pair connected across the secondary winding. The method can further include time-aligning the digital samples representative of the phase voltages Va, Vb, Vc and the reference voltage Vn prior to determining the phase-differential voltages.

### BRIEF DESCRIPTION OF THE DRAWINGS

Various aspects and advantageous features will become more apparent to those of ordinary skill when described in the detailed description and reference to the accompany drawings.

FIG. 1 depicts an exemplary configuration of an intelligent electronic device (“IED”) having a plurality of sensors connected to various phases A, B, C and neutral N of an electrical distribution system according to various embodiments disclosed herein.

FIG. 2A depicts an exemplary block diagram of a utility voltage meter with enhanced current and voltage measurement and processing according to various embodiments disclosed herein.

FIG. 2B depicts the three phases of voltage inputs to the exemplary block diagram of FIG. 2A.

FIG. 3 depicts an exemplary circuitry configuration of the front end offset circuitry and transimpedance circuit of a utility voltage meter with enhanced current and voltage measurement and processing according to various embodiments disclosed herein.

FIG. 4 depicts an exemplary circuitry configuration of the single power rail circuitry of a utility voltage meter with enhanced current and voltage measurement and processing according to various embodiments disclosed herein.

### DETAILED DESCRIPTION

In certain implementations, intelligent electronic devices (“IEDs”) sense electrical parameters and compute data and can be any device including, but not limited to, Programmable Logic Controllers (“PLC's”), Remote Terminal Units (“RTU's”), electric power meters, panel meters, protective relays, fault recorders, phase measurement units, serial switches, smart input/output devices and other devices which are coupled with power distribution networks to manage and control the distribution and consumption of electrical power. A meter is a device that records and measures power events, power quality, current, voltage waveforms, harmonics, transients and/or other power disturbances. Revenue accurate meters (“revenue meter”) relate to revenue accuracy electrical power metering devices with the ability to detect, monitor, report, quantify and communicate power quality information about the power that they are metering.

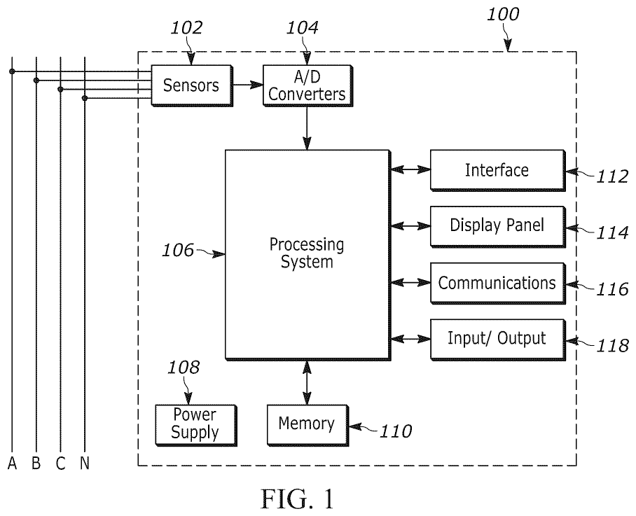

FIG. 1 depicts an exemplary configuration of an IED 100 having a plurality of sensors 102 connected to phases A, B, C and neutral N of an electrical distribution system according to various embodiments disclosed herein. In this embodiment one or more analog-to-digital (A/D) converters 104 are connected to the sensors 102. The A/D converters 104 connect the sensors 102 to the processing system 106. The processing system 106 can include any combination of processing components such as, for example, a CPU, a microcontroller, digital signal processors, field programmable gate arrays, a programmable logic device, or like types of processing circuitry as known by those of ordinary skill in the art.

The IED 100 may include a power supply 108 to supply power to the various components. In other implementations power may be supplied from an external source and routed into the IED 100 via a power supply line. One or more memory units 110 is connected to the processing system 106 The processing system 106 can be in communication with a user interface 112, a display panel 114, a communication interface 116, and one or more input/output ports 118.

The plurality of sensors 102 sense electrical parameters, e.g., voltage and current, on incoming lines, (i.e., phase A, phase B, phase C and neutral N) from an electrical power distribution system. In certain configurations, the sensors 102 can include current transformers and potential transformers. For example, one current transformer and one voltage transformer may be coupled to each phase of the incoming power lines. A primary winding of each transformer can be coupled to the incoming power lines and a secondary winding of each transformer will output a voltage representative of the sensed voltage and current.

The output of each transformer will be coupled to the A/D converters 104 configured to convert the analog output voltage from the transformer to a digital signal that can be processed by the processing system 106. A/D converters 104 are respectively configured to convert an analog voltage output to a digital signal that is transmitted to the processing system 106 to be processed. The processing system 106 is configured to operatively receive digital signals from the A/D converters 104 and to perform calculations necessary to determine power usage and to control the overall operations of the IED 100.

The power supply 108 provides power to each component of the IED 100. In certain configurations, the power supply 108 is a transformer with its primary windings coupled to the incoming power distribution lines and having windings to provide a nominal voltage, e.g., 5 VDC, +12 VDC and −12 VDC, at its secondary windings. In other configurations, power may be supplied from an independent power source to the power supply 108. For example, power may be supplied from a different electrical circuit or an uninterruptible power supply (UPS). In other configurations, the power supply can be a DC power supply such as a battery or rechargeable battery.

In some configurations, the power supply 108 can be a switch mode power supply in which the primary AC signal will be converted to a form of DC signal and then switched at high frequency, such as, for example, 100 Khz, and then brought through a transformer to step the primary voltage down to, for example, 5 Volts AC. A rectifier and a regulating circuit would then be used to regulate the voltage and provide a stable DC low voltage output. Other embodiments, such as, but not limited to, linear power supplies or capacitor dividing power supplies are also contemplated.

The IED 100 may further comprise a memory unit 110 which can include one or more memory components, such as volatile memory and non-volatile memory. In addition to storing audio and/or video files, memory 110 can store the sensed and generated data for further processing and for retrieval when called upon to be displayed at the IED 100 or from a remote location. The memory 110 can include any combination of: internal storage memory, e.g., random access memory (RAM); removable memory such as magnetic storage memory; optical storage memory, e.g., the various types of CD and DVD media; solid-state storage memory, e.g., a CompactFlash card, a Memory Stick, SmartMedia card, MultiMediaCard (MMC), SD (Secure Digital) memory; or any other type of memory storage as are known by those of ordinary skill in the art, or types of memory storage that will exist in the future. By utilizing removable memory, an IED can be easily upgraded as needed. Such memory will be used for storing historical trends, waveform captures, event logs including time-stamps and stored digital samples for later downloading or being sent to a client application, web-server or PC application.

The user interface 112 is connected to the processing system 106 for interacting with a user and for communicating events, such as alarms and instructions to the user. The interface 112 may include any set of physical inputs, such as buttons, touch screens, dials, etc. The user interface 112 further includes a speaker or audible output means for audibly producing instructions, alarms, data, etc. The speaker is typically coupled to the processing system 106 via a digital-to-analog converter (D/A) for converting digital audio files stored in memory 110.

The IED 100 may also include a display 114 for providing visual indications to the user. The display may be embodied as a touch screen, a liquid crystal display (LCD), a plurality of LED number segments, individual light bulbs or any combination. The display 114 can provide information to the user in the form of alpha-numeric lines, computer-generated graphics, videos, animations, etc.

The IED 100 will typically support one or more of various file types including but not limited to Microsoft Windows Media Video files (.wmv), Microsoft Photo Story files (.asf), Microsoft Windows Media Audio files (.wma), MP3 audio files (.mp3), JPEG image files (.jpg, .jpeg, .jpe, .jfif), MPEG movie files (.mpeg, .mpg, .mpe, .m1v, .mp2v .mpeg2), Microsoft Recorded TV Show files (.dvr-ms), Microsoft Windows Video files (.avi) and Microsoft Windows Audio files (.wav).

In certain implementations, the IED 100 includes a communication device 116, also known as a network interface, for enabling communications between the IED or meter, and a remote terminal unit, programmable logic controller and other computing devices, microprocessors, a desktop computer, laptop computer, other meter modules, etc. The communication device 116 can be a modem, network interface card (NIC), wireless transceiver, etc. The communication device 116 will perform its functionality by hardwired and/or wireless connectivity. The hardwire connection may include but is not limited to hard wire cabling e.g., parallel or serial cables, RS232, RS485, USB cable, Firewire (1394 connectivity) cables, Ethernet, and the appropriate communication port configuration. The wireless connection will operate under any of the various wireless protocols including but not limited to Bluetooth™ interconnectivity, infrared connectivity, radio transmission connectivity including computer digital signal broadcasting and reception commonly referred to as Wi-Fi or 802.11.X (where x denotes the type of transmission), satellite transmission or any other type of communication protocols, communication architecture or systems currently existing or to be developed for wirelessly transmitting data including spread spectrum 900 MHz, or other frequencies, Zigbee, WiFi, or any mesh enabled wireless communication.

The IED 100 can communicate to a server or other computing device via the communication device 116. The IED 100 can be connected to a communications network, e.g., the Internet, by any means, for example, a hardwired or wireless connection, such as dial-up, hardwired, cable, DSL, satellite, cellular, PCS, wireless transmission (e.g., 802.11a/b/g), etc. It is to be appreciated that the network may be a local area network (LAN), wide area network (WAN), the Internet or any network that couples a plurality of computers to enable various modes of communication via network messages. Furthermore, the server will communicate using various protocols such as Transmission Control Protocol/Internet Protocol (TCP/IP), File Transfer Protocol (FTP), Hypertext Transfer Protocol (HTTP), etc. and secure protocols such as Hypertext Transfer Protocol Secure (HTTPS), Internet Protocol Security Protocol (IPSec), Point-to-Point Tunneling Protocol (PPTP), Secure Sockets Layer (SSL) Protocol, etc. The server will further include a storage medium for storing a database of instructional videos, operating manuals, etc., the details of which will be described in detail below.

In an additional configuration, the IED 100 can also have the capability of not only digitizing waveforms, but storing the waveform and transferring that data upstream to a central computer, e.g., a remote server, when an event occurs such as a voltage surge or sag or a current short circuit. This data will be triggered and captured on an event, stored to memory, e.g., non-volatile RAM, and additionally transferred to a host computer within the existing communication infrastructure either immediately in response to a request from a remote device or computer to receive said data in response to a polled request. The digitized waveform will also allow the processing system 106 to compute other electrical parameters such as harmonics, magnitudes, symmetrical components and phasor analysis. Using the harmonics, the IED 100 will also calculate dangerous heating conditions and can provide harmonic transformer derating based on harmonics found in the current waveform.

In a further configuration, the IED 100 can execute an e-mail client and will send e-mails to the utility or to the customer direct on an occasion that a power quality event occurs. This allows utility companies to dispatch crews to repair the condition. The data generated by the meters are used to diagnose the cause of the condition. The data is transferred through the infrastructure created by the electrical power distribution system. The email client will utilize a POP3 or other standard mail protocol. A user will program the outgoing mail server and email address into the meter.

The techniques of the present disclosure can be used to automatically maintain program data and provide field wide updates upon which IED firmware and/or software can be upgraded. An event command can be issued by a user, on a schedule or by digital communication that will trigger the IED 100 to access a remote server and obtain the new program code. This will ensure that program data will also be maintained allowing the user to be assured that all information is displayed identically on all units.

It is to be understood that the present disclosure may be implemented in various forms of hardware, software, firmware, special purpose processors, or a combination thereof. The IED 100 also includes an operating system and micro instruction code. The various processes and functions described herein may either be part of the micro instruction code or part of an application program (or a combination thereof) which is executed via the operating system.

It is to be further understood that because some of the constituent system components and method steps depicted in the accompanying figures may be implemented in software, or firmware, the actual connections between the system components (or the process steps) may differ depending upon the manner in which the present disclosure is programmed. Given the teachings of the present disclosure provided herein, one of ordinary skill in the related art will be able to contemplate these and similar implementations or configurations of the present disclosure.

The components and devices of the IED 100 can be positioned in various depending on the application or working environment. For example, the components can be positioned in a panel meter, socket meter, switchboard or draw-out type housing, A-base or type A housing. Other housings and mounting schemes are within the scope of this disclosure.

Additionally, the IED 100 can be implanted in various environments. For example, the IED 100 can be implemented in a network, such as public or private network, WAN, LAN, or other type of network. The IED 100 can be connected over the network to various other devices, such as through client/server networks, peer-to-peer networks, mesh networks, etc.

Examples of certain housings, environments, and other features that can be incorporated in the IED 100 are shown and described in U.S. Published Application 2020/0012488, the contents of which are hereby incorporated herein by reference in their entirety.

A system for operating the electronic power meter may include a plurality of interconnected subsystems that cooperate to perform electrical parameter measurement and processing. The system may comprise a sensing subsystem, a signal conditioning subsystem, a conversion subsystem, a processing subsystem, a power management subsystem, a communication subsystem, and a user interface subsystem. Each subsystem may be configured to perform specific functions while interfacing with other subsystems to achieve overall system operation.

The sensing subsystem may include one or more current transformers positioned to sense current flowing through electrical conductors. Each current transformer may be configured with a primary winding and a secondary winding. The primary winding may be coupled to or positioned around a conductor carrying the current to be measured. The secondary winding may output a scaled current sample proportional to the primary current. The sensing subsystem may further include voltage sensing elements configured to sense voltage on phase conductors and a reference conductor. The voltage sensing elements may comprise potential transformers or resistive voltage dividers that scale high voltages to levels suitable for subsequent processing.

The signal conditioning subsystem may receive the current samples from the current transformers and the voltage signals from the voltage sensing elements. For current signal conditioning, the subsystem may include offset circuitry and transimpedance amplifier circuitry for each current measurement channel. The offset circuitry may be configured to establish a bias voltage for the current transformer secondary winding. The offset circuitry may include protection elements such as back-to-back diode pairs connected across the current transformer terminals. The offset circuitry may further include an operational amplifier configured to maintain the current transformer lower terminal at a reference voltage level.

The transimpedance amplifier circuitry may be configured to convert the current samples to voltage signals. Each transimpedance amplifier may include an operational amplifier with a feedback resistor connected between the amplifier output and inverting input. The non-inverting input of the operational amplifier may be connected to a reference voltage. The inverting input may receive the current sample from the current transformer. The feedback resistor may determine the transimpedance gain of the amplifier. A feedback capacitor may be connected in parallel with the feedback resistor to provide frequency compensation and bandwidth limiting.

For voltage signal conditioning, the subsystem may include scaling circuitry, filtering circuitry, and buffering circuitry for each voltage measurement channel. The scaling circuitry may reduce high voltages to levels compatible with analog-to-digital conversion. The filtering circuitry may remove high-frequency noise and limit bandwidth. The buffering circuitry may provide impedance matching between the voltage sensing elements and subsequent conversion circuitry.

The conversion subsystem may include one or more analog-to-digital converters configured to convert the conditioned analog signals to digital representations. The analog-to-digital converters may be integrated within a processor or microcontroller. The conversion subsystem may include multiple converter channels to accommodate simultaneous sampling of multiple signals. For voltage measurements, the conversion subsystem may be configured to simultaneously sample a phase voltage and a reference voltage using separate converter channels. This simultaneous sampling may ensure that the samples represent the same instant in time.

The conversion subsystem may implement oversampling techniques to reduce noise in the digital samples. The subsystem may be configured to perform multiple conversions of each analog signal and average the results. The number of samples in the oversampling process may be eight, though other oversampling ratios may be employed. The averaging process may reduce random noise by a factor related to the square root of the number of samples.

The processing subsystem may include one or more processors configured to execute firmware or software instructions. The processor may be a microcontroller, microprocessor, digital signal processor, field programmable gate array, or combination thereof. The processing subsystem may receive digital samples from the conversion subsystem and perform various computational operations.

The processing subsystem may implement correction algorithms to improve measurement accuracy. An offset correction algorithm may retrieve stored offset coefficients from memory and apply additive corrections to the digital samples. A gain correction algorithm may retrieve stored gain coefficients and apply multiplicative corrections. A linearization algorithm may apply a correction function to compensate for non-linearity in the measurement chain. The correction function may be implemented as a lookup table with interpolation or as a polynomial equation.

For voltage measurements involving multiple channels, the processing subsystem may implement a differential calculation algorithm. This algorithm may compute the difference between a phase voltage sample and a reference voltage sample on a sample-by-sample basis. The differential calculation may eliminate common-mode voltages present on both the phase and reference channels. The processing subsystem may perform this differential calculation for each phase voltage channel.

The processing subsystem may compute various electrical parameters from the corrected digital samples. Root-mean-square calculations may determine effective voltage and current values. Power calculations may multiply corresponding voltage and current samples to determine instantaneous power, which may be averaged over time to determine real power. Apparent power may be calculated from the product of RMS voltage and RMS current. Reactive power may be derived from real power and apparent power. Power factor may be calculated as the ratio of real power to apparent power.

The processing subsystem may perform frequency domain analysis of the digital samples. A Fast Fourier Transform or Discrete Fourier Transform algorithm may decompose the time-domain waveforms into frequency components. The magnitude and phase of each harmonic component may be extracted. Total harmonic distortion may be calculated from the harmonic magnitudes. Phasor representations of voltage and current may be computed, including magnitude and phase angle.

The processing subsystem may integrate power measurements over time to determine energy consumption. Accumulated energy may be stored in non-volatile memory. The processing subsystem may maintain separate energy accumulations for real energy and reactive energy. Time-stamped energy data may be stored for historical analysis and billing purposes.

The processing subsystem may implement event detection algorithms that monitor computed parameters for threshold violations. Voltage sag detection may identify when voltage drops below a threshold for a specified duration. Voltage swell detection may identify when voltage exceeds a threshold. Transient detection may identify rapid voltage or current changes. Harmonic distortion monitoring may identify when harmonic levels exceed limits. Upon detecting an event, the processing subsystem may trigger data logging, waveform capture, and alarm notification.

The power management subsystem may provide operating power to all system components. The subsystem may include a power input stage that receives alternating current or direct current power from an external source. For alternating current inputs, the subsystem may include rectification circuitry to convert the alternating current to direct current. The subsystem may include voltage regulation circuitry to produce a stable direct current output voltage.

The power management subsystem may implement a single-rail power supply architecture. The subsystem may generate a single positive voltage rail relative to ground. A reference voltage generator within the subsystem may produce a reference voltage at a midpoint between the positive rail and ground. This reference voltage may serve as a signal reference for analog circuitry. The reference voltage generator may include a voltage divider, a buffer amplifier, and filtering capacitors. The buffer amplifier may provide low output impedance to maintain reference voltage stability under varying load conditions.

The power management subsystem may distribute the positive voltage rail, the reference voltage, and ground to all system components. Decoupling capacitors may be positioned at each component to reduce noise and maintain local voltage stability. The subsystem may implement separate power distribution for analog and digital circuits to minimize noise coupling. Analog and digital ground planes may be connected at a single point to prevent ground loops.

The communication subsystem may enable data exchange between the electronic power meter and external devices or systems. The subsystem may include one or more communication interfaces. Wired communication interfaces may include serial ports implementing protocols such as RS-232 or RS-485. Ethernet interfaces may provide network connectivity using TCP/IP protocols. Universal Serial Bus interfaces may enable direct connection to computing devices.

Wireless communication interfaces may include Wi-Fi transceivers for wireless network connectivity. Bluetooth transceivers may provide short-range wireless communication. Cellular modems may enable remote connectivity via cellular networks. Mesh network radios may facilitate communication in distributed metering networks.

The communication subsystem may implement various communication protocols. Modbus protocol may be used for industrial automation communication. DNP3 protocol may be used for utility communication. IEC 61850 protocol may be used for substation automation. Proprietary protocols may be implemented for manufacturer-specific

The system may achieve high measurement accuracy through the combination of hardware design and signal processing techniques. The transimpedance amplifier topology may minimize phase shift in current measurements, enabling accurate power measurements across a wide frequency range. The single-rail power supply with midpoint reference may reduce circuit complexity while maintaining signal quality. The four-channel voltage measurement with differential calculation may eliminate common-mode errors. Oversampling and averaging may reduce random noise. Calibration-based correction may eliminate systematic errors.

In certain implementations, the IED may be configured to use one or more current transformers (which may be abbreviated as CT) to sense the current passing through a wire. A fraction of the sensed current may be provided as a sample by sampling circuitry of the IED. The current transformers are typically tied to a burden resistor to convert the sampled current into a voltage to obtain a voltage signal. This allows the voltage signal to be processed with voltage amplifiers or differential amplifiers.

Instead of using a burden resistor, the sampling circuitry of the various embodiments may use a transimpedance amplifier connected to the current transformer. This provides a conversion of the current sample to voltage for further processing, thus reducing the phase shift of the signal. Use of the transimpedance amplifier also reduces the impedance that the current transformer sees.

Using a transimpedance amplifier directly with the current transformer allows for a wider frequency range of operation. Use of a transimpedance amplifier in this way also keeps the difference of voltage between the current transformer terminals near to zero, which tends to provide a more accurate reading of the sampled current. Moreover, the architecture of the circuit provides a floating point for the middle reference of the spawn of the voltage. Use of the transimpedance amplifier front-end circuit can allow for the use of more cost effective current transformers which can be configured smaller in size than conventional devices.

In certain implementations, the IED can utilize a single power rail to measure one or more parameters of a utility system. Conventional meters typically use bipolar (dual symmetrical) power rails to process positive and negative signals in the analog circuit. In certain configurations, the IED can use a single power rail for the analog measurements. The novel use of a single rail in this manner aids in reducing circuit size and cost.

For single rail circuit configurations according to the various embodiments the topology of the analog front end is designed to use a middle voltage point of the power rail as a reference for the analog signals. The single rail configuration may entail some complexity for the generation of the middle voltage point—e.g., in providing stability, accuracy and low noise. However, the single rail circuit configuration allows for less complexity in the rest of the analog circuit, thus reducing circuitry costs. Further, the single rail circuit configuration tends to reduce power consumption in comparison to conventional bipolar power circuit designs.

In certain implementations, the IED can utilize four channels for voltage readings (Va, Vb, Vc, Vn) instead of utilizing three channels (Va, Vb, Vc). For example, the IED can include firmware configured to compute a sample-by-sample differentiation between the three voltage phases—that is, between Va, Vb and Vc. The firmware also computes sample differentiation to the Vn channel to get the correct voltage for each phase, thus eliminating the common voltage. The various embodiments may be configured to use two simultaneous analog-to-digital converters. This assures that the sample of the voltage taken for each phase and for the Vn occur at the same moment in time.

In certain implementations, the IED can use internal analog-to-digital converters (ADC) to obtain measurements of a utility system internally to the IED.

The various embodiments disclosed herein may be configured to use the internal analog-to-digital converter of the processor to convert the analog signals coming from the exterior—e.g., for voltage and/or current. In the various implementations there may be an electronic preprocessing of the signals (e.g., the front end) but at the end the internal ADC converts the signal to a number.

In certain implementations, oversampling can be used to help prevent or limit noise in the signal. For example, the various implementations may be configured to feature oversampling of the converted signal—e.g., oversampling of eight. This is achieved by converting the signal eight times and averaging the result. Oversampling in this way tends to minimize the noise.

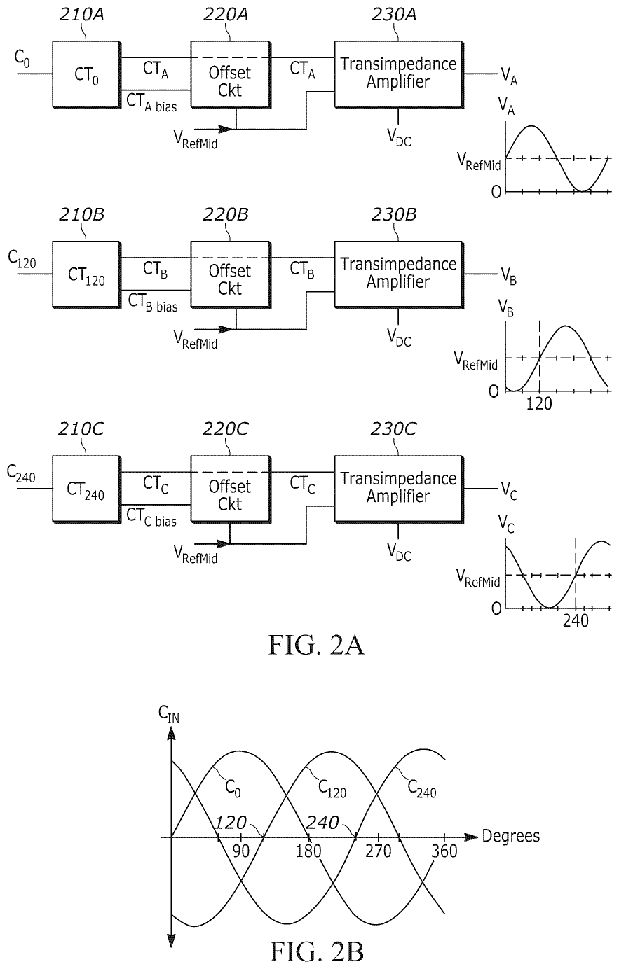

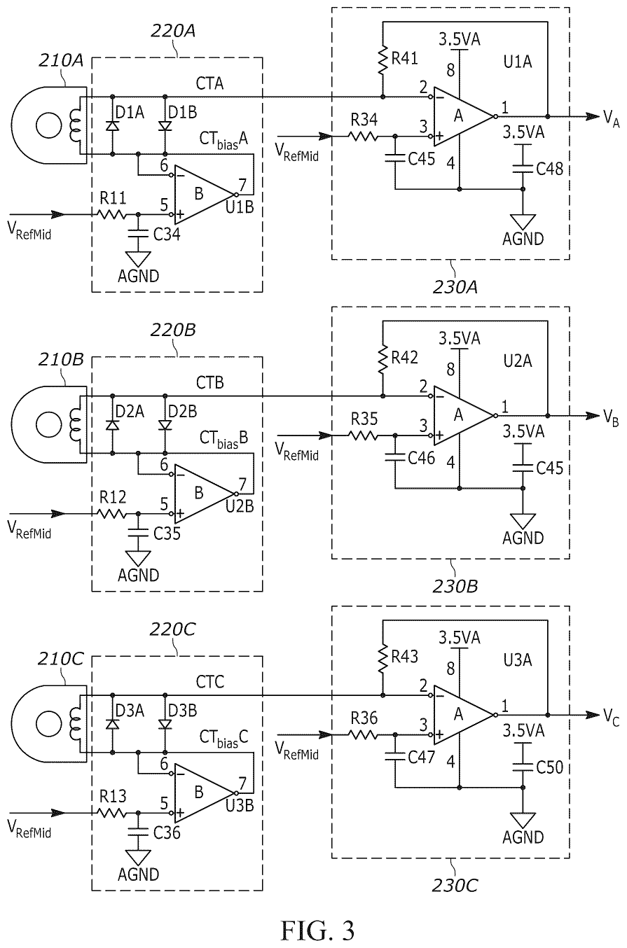

Another noise reduction feature can include offset and linearization. This may be done, for example, by offset/linearization logic configured within the electronic power meter—e.g., within offset circuitry 220A-C of FIG. 2A. The offset and linearization methods involve a correction of the read signal based on a previous calibration process. Simultaneous sampling is another way of producing increasingly accurate readings. Simultaneous sampling uses readings from two analog-to-digital converters—one on the phase signal and one on the reference signal for each phase. In this way the difference can be processed as a real phase signal. Previously a specific chip was used for this operation. The new implementation according to various embodiments tends to provide a cost reduction. The over sampling technique and the overall sampling frequency also result in increased granularity of the observed signal.

FIG. 2A depicts an exemplary block diagram of a utility voltage meter with enhanced current and voltage measurement and processing according to various embodiments disclosed herein. FIG. 2B depicts the three phases of current—currents C₀, C₁₂₀ and C₂₄₀—that are input to the exemplary block diagram of FIG. 2A. Currents C₀, C₁₂₀ and C₂₄₀ may be from a three-phase transmission line. As shown in FIG. 2B the current C₁₂₀ lags current C₀ by 120 degrees, and current C₂₄₀ lags current C₁₂₀ by 120 degrees. Similarly, the three output voltages V_{A}, V_{B} and V_{C} shown in FIG. 2A are 120 degrees apart.

The C₀ input current into current transformer 210A (CT₀) results in voltage V_{A} output from transimpedance amplifier 230A. Similarly, the C₁₂₀ input current into current transformer 210B (CT₁₂₀) results in voltage V_{B} output from transimpedance amplifier 230B, and the C₂₄₀ current input into current transformer 210C (CT₂₄₀) results in voltage V_{C} output from transimpedance amplifier 230C. It should be noted that the input currents (e.g., C₀) and the currents corresponding to the output voltages (e.g., V_{A}) are not in phase (or rather, are not likely to be in phase) due to the phase shift of the intervening circuitry. But the phase relationship of the three output voltages relative to each other is similar to that of the input currents. That is, voltage V_{B} lags voltage V_{A} by 120 degrees, and voltage V_{C} lags V_{B} by 120 degrees.

The utility voltage meter uses current transformers (CTs) 210A-C to sense the current passing each of the three wires of a three-phase power line. Current transformers 210A-C each provide a fraction of the received currents as sample currents CT_{A}, CT_{B} and CT_{C}. In conventional systems the current transformers are each tied to a burden resistor to convert the sampled current into a voltage for further processing and measurement. Instead of this approach, the various embodiments disclosed herein respectively feed the sampled currents CT_{A}, CT_{B} and CT_{C} through offset circuitry 220A-C and into transimpedance amplifiers 230A, 230B and 230C. The offset circuitry 220A-C provides a floating point for the middle reference of the spawn of the voltage.

The transimpedance amplifiers 230A-C provide for the conversion of the current samples CT_{A}, CT_{B} and CT_{C} to voltages for further processing. This reduces the phase shift of the signal and also reduces the impedance to the current transformers 210A-C—that is, it reduces the impedance that the current transformers 210A-C see. The transimpedance amplifiers 230A-C allow a wider frequency range of operation, and aid in keeping the difference of voltage between the terminals of the current transformers 210A-C near to zero. Keeping the voltage between the current transformers 210A-C terminals near to zero tends to favor the accuracy of the sampled current. This improvement is made possible by the architecture of the offset circuitry 220A-C which provides a floating point for the middle reference of the spawn of the voltage. The V_{DC} input to each of the transimpedance amplifiers 230A-C is used to bias the op amp in the transimpedance circuit. In various implementations V_{DC} is 3.5 VDC, but could be 2.5 VDC, 5.0 VDC or another DC voltage, depending upon the choice of components (e.g., the op amp) and configuration of the circuit.

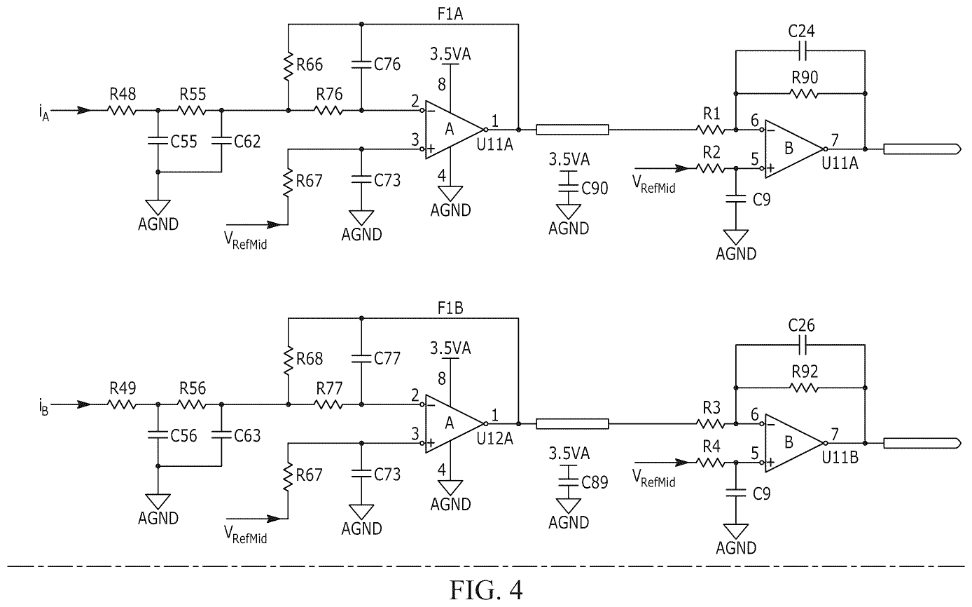

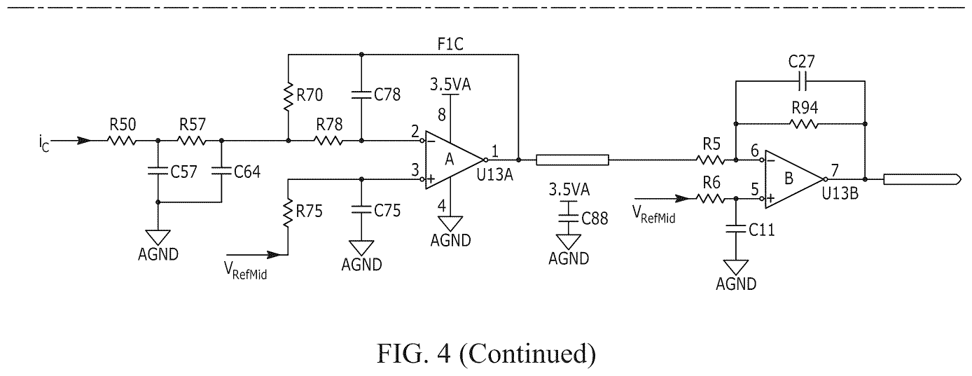

In certain implementations, the utility voltage meter uses a single power rail for the analog measurements. By contrast, conventional meters use bipolar (dual symmetrical) power rails to process positive and negative signals in the analog circuit. The single rail circuit is realized in the various embodiments by changing the topology of the analog front end to use a middle voltage point V_{RefMid} of the power rail as a reference for the analog signals. The reference voltage V_{RefMid} is provided to the offset circuitry 220A-C and to transimpedance amplifiers 230A-C. FIGS. 3-4 provide further details of circuitry for implementing the functional blocks depicted in FIG. 2A.

FIG. 3 depicts an exemplary circuitry configuration of the front end trans-impedance circuit of a utility voltage meter with enhanced current and voltage measurement and processing according to various embodiments disclosed herein. The front end transimpedance circuit includes circuitry configurations that implement the current transformers 210A-C, offset circuitry 220A-C and transimpedance amplifiers 230A-C of FIG. 2A. The currents inputs to current transformers 210A-C are C₀, C₁₂₀ and C₂₄₀ (not shown) and may be from a three-phase transmission line. The currents inputs C₀, C₁₂₀ and C₂₄₀ are phased 120 degrees apart, as reflected in FIG. 2A. As such, the three output voltages V_{A}, V_{B} and V_{C} shown in FIG. 2B are 120 degrees apart, as described above in conjunction with FIG. 2A.

The offset circuitry 220A includes a back-to-back diode pair formed by diodes D1A and D1B positioned across the terminals of current transformer 210A. The lower terminal of current transformer 210A is connected to the back-to-back diode pair D1A and D1B, and also connected to the negative input (sometimes called inverting input) of op amp U1B and to the output of U1B. The positive U1B op amp input (sometimes called noninverting input) is connected to DC voltage V_{RefMid}. The effect of this is to produce a bias voltage (offset) at CT_{biasA} at the output of op amp U1B which is tied to the lower terminal of current transformer 210A.

The sample current CT_{A} from the upper terminal of current transformer 210A is input to the negative terminal of op amp U1A within transimpedance amplifier 230A. The positive input of op amp U1A is tied to DC voltage V_{RefMid}. Op amp U1A is tied to ground on one side, and provided with a voltage supply of 3.5 volts. Feedback resistor R41 is connected between the output of op amp U1A and its negative input terminal. The capacitor C45 is connected between the positive input terminal of op amp U1A and ground. The gain of transimpedance amplifier 230A may be adjusted by selecting the value of feedback resistor R41 and capacitor C45.

Current transformers 210B-C operate in a manner similar to current transformer 210A. Offset circuitry 220B-C operates in a manner similar to offset circuitry 220A. Transimpedance amplifiers 230B-C operate in a manner similar to transimpedance amplifier 230A.

FIG. 4 depicts an exemplary circuitry configuration of the single power rail circuitry of a utility voltage meter with enhanced current and voltage measurement and processing according to various embodiments disclosed herein. FIG. 4 depicts another implementation of offset circuitry 220A-C and transimpedance amplifiers 230A-C shown in FIGS. 2A and 3. The offset circuitry 220A-C provides a middle reference voltage spawn from the power supply. The transimpedance amplifiers 230A-C provide for the conversion of the current samples CT_{A}, CT_{B} and CT_{C} to voltages V_{A}, V_{B} and V_{C} for further processing (as labeled in FIG. 2A).

The utility voltage meter according to the various disclosed embodiments uses a single power rail for the analog measurements. This differs from conventional meters that use bipolar (i.e., dual symmetrical) power rails to process positive and negative signals in the analog circuit. The single power rail design of the various embodiments aids in reducing circuit size and manufacturing costs. The single rail circuit is achieved by the architecture of the offset circuitry 220A-C in the analog front end of the utility meter. A middle voltage point V_{RefMid} of the power rail is used as a reference for the analog signals.

The circuit topology shown in FIG. 4 may demonstrate several key features of the single power rail architecture. The use of a single positive supply voltage (3.5VA) and analog ground (AGND) may simplify the power supply design and may reduce the number of components required compared to a bipolar supply configuration. The generation and distribution of the VRefMid reference voltage may enable the circuit to process AC signals that swing both positive and negative relative to the reference, effectively creating a bipolar signal range within the single-rail power constraints.

The transimpedance amplifier stages (U11A and U12A) may convert the input currents iA and iB into voltage signals while maintaining low input impedance. The low input impedance may minimize the burden on the current transformers that provide the input currents, which may allow for the use of smaller and less expensive current transformers. The feedback networks associated with the transimpedance amplifiers may be configured to provide appropriate gain and frequency response for accurate measurement of the fundamental frequency and harmonics present in the electrical distribution system.

The upper amplifier stages (U11A and U11B) may provide additional gain and buffering of the signals before they are output to subsequent processing stages. The feedback networks in the upper stages may be configured to establish the overall gain and frequency response of each channel. The use of parallel resistor-capacitor feedback networks may allow for frequency-dependent gain characteristics that can be tailored to the specific requirements of the measurement application.

The decoupling capacitors (C90, C89, C73) may be strategically placed throughout the circuit to maintain signal integrity and to prevent noise coupling between different portions of the circuit. The decoupling of the VRefMid reference voltage may be particularly important, as any noise or instability in the reference voltage may directly affect the accuracy of the signal processing. The output decoupling capacitors may filter high-frequency components and may provide a stable output impedance for driving subsequent stages.

The circuit may be configured to operate over a wide frequency range, encompassing the fundamental power frequency (such as 50 Hz or 60 Hz) and its harmonics. The component values may be selected to ensure that the circuit maintains adequate gain and phase accuracy across this frequency range. The use of transimpedance amplification may minimize phase shift compared to traditional burden resistor approaches, which may be important for accurate power measurements that depend on the phase relationship between voltage and current.

The single power rail architecture may offer several operational advantages. The circuit may consume less power than a bipolar supply configuration, as only a single voltage regulator may be required. The reduced component count may lead to a smaller circuit board footprint and lower manufacturing costs. The simplified power distribution may also reduce the complexity of the circuit board layout and may minimize the potential for ground loops and other noise coupling mechanisms.

The circuit may be configured to provide protection against overvoltage and overcurrent conditions. The diodes shown in the circuit (such as the diode connected to capacitor C9) may clamp output voltages to safe levels. Additional protection components (not shown) may be included at the inputs to protect against transients and overvoltage conditions on the current transformer outputs. The circuit board layout may include appropriate spacing and creepage distances to ensure electrical safety and to meet relevant safety standards.

The analog ground AGND may be carefully managed in the circuit board layout to minimize noise coupling and ground loops. The AGND may be implemented as a dedicated ground plane or ground region on the circuit board, separate from digital ground regions. The connection between analog ground and digital ground may be made at a single point to prevent ground currents from flowing through the analog ground plane. This single-point grounding strategy may minimize noise injection into the sensitive analog signal paths.

The circuit may be configured to interface with subsequent digital processing stages. The output voltages from the upper amplifier stages may be routed to analog-to-digital converters (ADCs) that convert the analog signals to digital samples. The ADCs may be integrated within a microcontroller or processor, as described in earlier portions of this specification. The digital samples may then be processed by firmware to compute electrical parameters such as RMS voltage, RMS current, real power, reactive power, power factor, harmonics, and energy consumption.

The single power rail architecture and the use of the VRefMid reference voltage may enable the circuit to achieve accurate measurements while reducing cost and complexity. The circuit may provide performance comparable to traditional bipolar supply designs while offering the advantages of reduced component count, lower power consumption, and simplified power supply design. The circuit topology may be well-suited for integration into intelligent electronic devices (IEDs) and revenue meters where cost, size, and power consumption are important considerations.

The utility meter according to the various embodiments may provide several technical advantages through the synergistic combination of transimpedance amplification, single-rail power architecture, four-channel differential voltage measurement, and internal ADC utilization with advanced signal processing. Each of these technical features may contribute distinct advantages that collectively enhance measurement accuracy while reducing cost, size, and power consumption.

The transimpedance amplifier architecture employed in the various embodiments may provide multiple technical advantages over conventional burden resistor approaches for current measurement. The transimpedance amplifier may be configured to present very low input impedance to the current transformer secondary winding. This low impedance loading may minimize the burden on the current transformer, which may allow the current transformer to operate with reduced core saturation and improved linearity. The virtual ground maintained at the inverting input of the operational amplifier may keep the voltage difference between the current transformer terminals near zero. This near-zero voltage condition may reduce errors associated with current transformer magnetizing current and leakage inductance.

The transimpedance amplifier topology may provide significantly reduced phase shift compared to burden resistor configurations. In conventional burden resistor circuits, the impedance of the burden resistor combined with the current transformer secondary inductance may create a phase shift that varies with frequency. This phase shift may introduce errors in power measurements, particularly when measuring reactive power or power factor. The transimpedance amplifier may minimize this phase shift by maintaining the current transformer secondary terminals at virtual ground potential. The feedback resistor in the transimpedance configuration may perform the current-to-voltage conversion without creating the voltage drop across the current transformer terminals that would otherwise introduce phase errors.

The transimpedance amplifier architecture may enable operation over a wider frequency range than conventional burden resistor circuits. The low input impedance presented to the current transformer may extend the useful frequency response to higher harmonics. This extended frequency response may be particularly advantageous for measuring harmonic content in power distribution systems. Modern power systems may contain significant harmonic distortion due to non-linear loads such as variable frequency drives, switching power supplies, and electronic ballasts. The ability to accurately measure harmonics up to the 50th or higher may provide more complete power quality information.

The transimpedance amplifier configuration may allow the use of smaller and less expensive current transformers compared to conventional designs. The reduced burden impedance may permit the use of current transformers with smaller cores and fewer secondary turns. Smaller current transformers may reduce the physical size and weight of the meter. The cost reduction from using smaller current transformers may be substantial, particularly in multi-phase metering applications requiring multiple current transformers. The reduced size may also facilitate installation in space-constrained environments such as electrical panels and switchboards.

The single power rail architecture employed in the various embodiments may provide several technical and economic advantages over conventional bipolar power supply designs. Conventional meters may typically use bipolar power supplies providing positive and negative voltage rails, such as +15V/0V/−15V or +5V/0V/−5V configurations. The single rail architecture may eliminate the negative voltage rail entirely, using only a positive voltage rail and ground. This simplification may reduce the number of power supply components required.

The single rail architecture may reduce component count by eliminating the negative voltage regulator, negative voltage filtering capacitors, and associated circuitry. Fewer components may translate directly to reduced bill of materials cost. The simplified power supply may also reduce printed circuit board area requirements. Reduced board area may allow for more compact meter designs or may provide space for additional functionality within the same form factor. The manufacturing process may be simplified with fewer components to place and solder, potentially reducing assembly time and cost.

The single rail power supply may consume less power than equivalent bipolar supplies. A single voltage regulator may dissipate less power than dual regulators. The reduced power consumption may be particularly advantageous in battery-powered or energy-harvesting applications. Lower power consumption may also reduce heat generation within the meter enclosure. Reduced heat generation may improve reliability by reducing thermal stress on electronic components. The lower operating temperature may extend the service life of electrolytic capacitors and other temperature-sensitive components.

The single rail architecture may simplify the power distribution network on the printed circuit board. With only one positive rail and ground to distribute, the power plane layout may be more straightforward. The simplified layout may reduce the potential for ground loops and other noise coupling mechanisms. The single rail design may also facilitate the use of low-dropout linear regulators for generating lower voltages from the main rail. Multiple voltage levels may be generated efficiently from a single input rail using buck converters or linear regulators as appropriate for each load.

The midpoint reference voltage generation may be a key enabler of the single rail architecture. The midpoint reference may be generated at half the supply voltage, creating a virtual ground for analog signal processing. This virtual ground may allow analog circuits to process bipolar signals that swing above and below the reference voltage. The midpoint reference generator may include precision voltage divider circuitry and a low-impedance buffer amplifier. The buffer amplifier may provide sufficient current sourcing and sinking capability to maintain stable reference voltage under varying load conditions. Extensive decoupling capacitors may be distributed throughout the analog circuitry to maintain local stability of the midpoint reference.

The four-channel differential voltage measurement architecture employed in the various embodiments may provide significant advantages over conventional three-channel voltage measurement systems. Conventional three-phase meters may typically measure three phase voltages using three voltage input channels. The various embodiments may add a fourth channel to measure the neutral or reference voltage. This fourth channel may enable sample-by-sample differential calculation between each phase voltage and the reference voltage.

The differential measurement approach may eliminate common-mode voltages that may be present on all measurement channels. Common-mode voltages may arise from several sources including ground potential differences, electromagnetic interference, and power supply noise. In conventional three-channel systems, these common-mode voltages may appear as measurement errors. The differential calculation may subtract the reference voltage from each phase voltage on a sample-by-sample basis. This subtraction may cancel common-mode components that are present on both the phase and reference channels.

The elimination of common-mode errors may significantly improve measurement accuracy in electrically noisy environments. Industrial facilities may contain numerous sources of electromagnetic interference including motors, drives, welders, and switching power supplies. These interference sources may couple noise into measurement circuits through capacitive, inductive, or conductive paths. The differential measurement may reject this coupled noise to the extent that it appears as common-mode voltage. The improved noise immunity may allow accurate measurements in environments where conventional meters might produce unreliable readings.

The four-channel architecture may also improve accuracy in systems with significant ground potential differences. In large facilities, the ground potential at the meter location may differ from the ground potential at the load location due to ground loop currents or voltage drops in the grounding system. These ground potential differences may appear as measurement errors in conventional systems. The differential measurement may reference all phase voltages to the same neutral point, eliminating errors due to ground potential variations.

The simultaneous sampling capability may be essential for accurate differential measurement. The various embodiments may employ two or more analog-to-digital converters operating in parallel to sample the phase voltage and reference voltage at the same instant in time. This simultaneous sampling may ensure that the samples represent the same moment in the AC waveform cycle. For rapidly varying AC signals, any time delay between samples may introduce errors in the differential calculation. The simultaneous sampling may eliminate these timing errors.

The four-channel differential architecture may be particularly advantageous for measuring voltage in three-phase four-wire systems. In such systems, the neutral conductor may carry unbalanced currents and may not be at ground potential. Measuring each phase voltage relative to the neutral may provide accurate phase-to-neutral voltage measurements regardless of the neutral voltage. This capability may be important for identifying unbalanced loading conditions and neutral-to-ground voltage issues.

The use of internal processor-integrated analog-to-digital converters with oversampling may provide several technical and economic advantages over conventional external ADC approaches. Meters may employ dedicated external ADC integrated circuits specifically designed for metering applications. These dedicated ADCs may offer high resolution and accuracy but may add significant cost to the meter design. The various embodiments may utilize ADCs integrated within the main processor or microcontroller. This integration may eliminate the cost of external ADC components.

The internal ADC approach may reduce printed circuit board complexity by eliminating external ADC chips and their associated passive components. Fewer components may simplify board layout and reduce board area. The reduced component count may also improve reliability by reducing the number of potential failure points. The internal ADCs may communicate with the processor core via internal buses, eliminating the need for external serial or parallel communication interfaces. This internal communication may reduce latency and may simplify software design.

The oversampling technique employed in the various embodiments may compensate for limitations of internal ADCs compared to dedicated metering ADCs. Internal processor ADCs may typically have higher noise levels and lower effective resolution than dedicated metering ADCs. The oversampling approach may address these limitations by sampling each signal multiple times and averaging the results. The various embodiments may employ 8× oversampling, meaning each signal may be sampled eight times per measurement interval.

The averaging of multiple samples may reduce random noise by a factor related to the square root of the number of samples. For 8× oversampling, the noise reduction factor may be approximately √8≈2.83. This noise reduction may improve the signal-to-noise ratio by approximately 9 dB. The improved signal-to-noise ratio may translate to increased effective resolution. Each doubling of the oversampling ratio may add approximately 0.5 bits of effective resolution. The 8× oversampling may therefore add approximately 1.5 bits of effective resolution to the ADC.

The oversampling technique may also improve the effective sampling rate for capturing transient events. While the final output data rate may be, for example, 8 kHz, the actual ADC sampling rate may be 64 kHz for 8× oversampling. This higher sampling rate may better capture fast transients and high-frequency components. The averaging process may then provide anti-aliasing filtering in the digital domain. This digital filtering may complement or reduce the requirements for analog anti-aliasing filters.

The calibration-based correction employed in the various embodiments may further enhance the accuracy of internal ADC measurements. The offset correction may eliminate DC offset errors that may be present in the ADC or signal conditioning circuitry. During calibration, known reference signals may be applied and the measured offsets may be stored in non-volatile memory. During normal operation, these stored offset values may be subtracted from each measurement. The linearization correction may compensate for non-linearity in the ADC transfer function. A lookup table or polynomial function may be applied to correct for deviations from ideal linear response.

The combination of transimpedance amplification, single-rail power supply, four-channel differential measurement, and internal ADC with oversampling may provide synergistic advantages that exceed the sum of individual benefits. The transimpedance amplifier may work particularly well with the single-rail power architecture because the midpoint reference voltage may provide the virtual ground needed for the transimpedance amplifier operation. The floating reference created by the offset circuitry may allow the current transformer to operate with the single-supply transimpedance amplifier while maintaining near-zero voltage across the current transformer terminals.

The four-channel differential measurement may complement the single-rail architecture by providing common-mode rejection that may compensate for any noise or instability in the single power rail. Any power supply noise that couples into the measurement channels may appear as common-mode voltage and may be rejected by the differential calculation. This common-mode rejection may allow the single-rail power supply to use simpler filtering than might otherwise be required.

The internal ADC with oversampling may work synergistically with the transimpedance amplifier's wide bandwidth. The transimpedance amplifier may provide signals with minimal phase shift and extended frequency response. The high sampling rate used for oversampling may capture this extended frequency content. The digital averaging may then provide controlled bandwidth limiting without introducing the phase shift that analog filters might introduce.

The cost reductions from each architectural element may compound to provide substantial overall cost savings. The smaller current transformers enabled by transimpedance amplification, the reduced component count from single-rail power supply, the elimination of external ADC chips, and the simplified signal conditioning may each contribute to lower bill of materials cost. The reduced component count may also reduce assembly cost and improve manufacturing yield. The smaller physical size may reduce packaging cost and may allow the meter to fit in more compact enclosures.

The improved accuracy from each architectural element may also compound. The reduced phase shift from transimpedance amplification, the common-mode rejection from differential measurement, the noise reduction from oversampling, and the error correction from calibration may each improve measurement accuracy. The combination may provide accuracy comparable to or exceeding that of conventional meters using more expensive components. This combination of reduced cost and maintained or improved accuracy may represent a significant advancement in metering technology.

The reduced power consumption from the single-rail architecture may be particularly advantageous when combined with the other features. The lower power consumption may allow the meter to operate from smaller power supplies or from energy harvesting sources. In battery-powered applications, the reduced power consumption may significantly extend battery life. The lower power consumption may also reduce heat generation, which may improve reliability and may allow the meter to operate in higher ambient temperature environments.

The architectural approach may also provide flexibility for future enhancements. The processor-based design with internal ADCs may allow firmware updates to add new features or improve existing algorithms. The oversampling approach may be adjusted in firmware to trade off between noise reduction and sampling rate as needed for different applications. The calibration coefficients may be updated in the field to maintain accuracy over the life of the meter. This flexibility may extend the useful life of the meter and may allow it to adapt to changing requirements.

The foregoing detailed description has been provided for the purpose of explaining the general principles and practical application, thereby enabling others skilled in the art to understand the disclosure for various configurations and implementations, and with various modifications as are suited to the particular uses contemplated. This description is not necessarily intended to be exhaustive or to limit the disclosure to what is disclosed. Any of the configurations and/or elements disclosed herein may be combined with one another to form various additional embodiments not specifically disclosed. Accordingly, additional configurations and implementations are possible and are intended to be encompassed within this specification and the scope of the appended claims. The specification describes specific examples to accomplish a more general goal that may be accomplished in another way. The specification labels the three voltage phases Va, Vb and Vc and the reference voltage Vn. In practice any labels may be used to identify the three voltage phases, and such labels are considered equivalents.

As used in this application, the terms “front,” “rear,” “upper,” “lower” and other orientational descriptors are intended to facilitate the description of the exemplary embodiments of the present disclosure, and are not intended to limit the structure of the exemplary embodiments of the present disclosure to any particular position or orientation. Terms of degree, such as “substantially” or “approximately” are understood by those of ordinary skill to refer to reasonable ranges outside of the given value, for example, general tolerances associated with manufacturing, assembly, and use of the described embodiments. Unless specified or limited otherwise, the terms “mounted,” “connected,” “supported,” and “coupled” and variations thereof are used broadly and encompass both direct and indirect mountings, connections, supports, and couplings. The words “member,” “component,” “module,” “mechanism,” “element,” “device,” and the like are not a substitute for the word “means.” As such, no claim element should be construed as a means plus function unless the element is expressly recited using the phrase “means for.”

Functionality described herein may be implemented by any combination of hardware, software, or firmware. Functionality described herein as being performed by one component may be performed by multiple components in a distributed manner. Likewise, functionality performed by multiple components may be consolidated and performed by a single component. Similarly, a component described as performing particular functionality may also perform additional functionality not described herein. For example, a device or structure that is “configured” in a certain way is configured in at least that way but may also be configured in ways that are not explicitly listed.

Certain electrical components are generally shown and described in terms of their functions or end results as it would be understood by one of ordinary skill viewing this disclosure that the exact structure, connections, and components can be varied to achieve the desired results. In addition, certain implementation may include hardware, software, and electronic components or modules that, for purposes of discussion, may be illustrated and described as if most of the components were implemented solely in hardware. However, one of ordinary skill in the art, and based on a reading of this disclosure would recognize that in certain configurations the electronic-based aspects may be implemented in software (e.g., stored on non-transitory computer-readable medium) executable by one or more processing units, such as any combination of one or more of a general-purpose processor, microprocessor, DSP, FPGA, application specific integrated circuits (“ASICs”), and/or other programmable logic device. As such, it should be noted that a plurality of hardware and software-based devices, as well as a plurality of different structural components, may be utilized to implement the embodiments. For example, “servers,” “computing devices,” “controllers,” “processors,” etc., described in the specification can include one or more processing units, one or more computer-readable medium modules, one or more input/output interfaces, and various connections (e.g., a system bus) connecting the components.

One of ordinary skill will appreciate that the exact dimensions and materials are not critical to the disclosure and all suitable variations should be deemed to be within the scope of the disclosure if deemed suitable for carrying out the objects of the disclosure. One of ordinary skill in the art will also readily appreciate that it is well within the ability of the ordinarily skilled artisan to modify one or more of the constituent parts for carrying out the various embodiments of the disclosure. Once armed with the present specification, routine experimentation is all that is needed to determine adjustments and modifications that will carry out the present disclosure.

The above embodiments are for illustrative purposes and are not intended to limit the scope of the disclosure or the adaptation of the features described herein. Those skilled in the art will also appreciate that various adaptations and modifications of the above-described preferred embodiments can be configured without departing from the scope and spirit of the disclosure. Therefore, it is to be understood that, within the scope of the appended claims, the invention may be practiced other than as specifically described.

What is claimed is:

1. An electronic power meter comprising:
a plurality of sensors configured to sense electrical parameters on a plurality of phases of an electrical power system;
at least one analog-to-digital converter configured to convert analog signals into digital data;
a processing system operatively coupled to the at least one analog-to-digital converter and configured to process the digital data;
a memory unit operatively coupled to the processing system; and
a current measurement front end coupled between the plurality of sensors and the at least one analog-to-digital converter, the current measurement front end including,
at least one current transformer configured to generate a current sample proportional to a current flowing in a conductor of the electrical power system;
offset circuitry electrically coupled to a secondary winding of the at least one current transformer and configured to bias terminals of the secondary winding to a reference voltage, and
a transimpedance amplifier electrically coupled to the secondary winding and to the offset circuitry, the transimpedance amplifier configured to convert the current sample into a voltage signal for input to the at least one analog-to-digital converter.

2. The electronic power meter of claim 1, wherein the offset circuitry comprises at least one diode pair connected across the secondary winding of the at least one current transformer and configured to limit a voltage across the secondary winding.

3. The electronic power meter of claim 1, wherein the transimpedance amplifier comprises an operational amplifier having a feedback resistor connected between an output terminal and an inverting input terminal and having a non-inverting input terminal biased to the reference voltage.

4. The electronic power meter of claim 1, wherein the transimpedance amplifier further comprises a feedback capacitor connected in parallel with a feedback resistor and configured to set a frequency response of the current measurement front end.

5. The electronic power meter of claim 1, wherein the current measurement front end comprises a plurality of current transformers respectively associated with a plurality of phases of the electrical power system and a plurality of transimpedance amplifiers respectively associated with the plurality of current transformers.

6. The electronic power meter of claim 1, wherein the offset circuitry is configured to maintain a voltage at the terminals of the secondary winding of the at least one current transformer within a predetermined range to reduce phase shift and loading of the at least one current transformer.

7. The electronic power meter of claim 1, further comprising a power supply configured to provide a single power rail having a supply voltage referenced to a ground node.

8. The electronic power meter of claim 7, further comprising an analog measurement circuitry coupled between the plurality of sensors and the at least one analog to digital converter, the analog measurement circuitry including, a middle voltage reference circuit configured to generate a middle voltage point between the supply voltage and the ground node, and one or more analog front end amplifiers powered from the single power rail and referenced to the middle voltage point and configured to generate one or more analog measurement signals for input to the at least one analog to digital converter.

9. A method of measuring current in an electronic power meter, the method comprising:
sensing, by at least one current transformer, a current flowing in a conductor of an electrical power system and generating a current sample proportional to the current;
biasing, by offset circuitry, terminals of a secondary winding of the at least one current transformer to a reference voltage;
converting, by a transimpedance amplifier electrically coupled to the secondary winding, the current sample into a voltage signal;
converting, by at least one analog-to-digital converter, the voltage signal into digital data; and
processing, by a processing system, the digital data to determine at least one current-related parameter of the electrical power system.

10. The method of claim 9, wherein biasing the terminals of the secondary winding comprises clamping a voltage across the secondary winding using at least one diode pair connected across the secondary winding.

11. The method of claim 9, wherein converting the current sample into the voltage signal comprises applying the current sample to an inverting input of an operational amplifier having a feedback resistor and biasing a non-inverting input of the operational amplifier to the reference voltage.

12. The method of claim 9, further comprising filtering the voltage signal using a feedback capacitor connected in parallel with a feedback resistor of the transimpedance amplifier.

13. The method of claim 9, wherein sensing the current comprises sensing a plurality of phase currents of the electrical power system using a corresponding plurality of current transformers and converting a plurality of current samples into a plurality of voltage signals using a corresponding plurality of transimpedance amplifiers.

14. The method of claim 9, wherein biasing the terminals of the secondary winding comprises maintaining a voltage across the secondary winding of the at least one current transformer below a threshold to reduce phase shift of the current transformer.

15. An electronic power meter comprising:
a plurality of sensors configured to sense electrical parameters on a plurality of phases of an electrical power system;
analog front-end circuitry coupled to the plurality of sensors and configured to generate analog measurement signals representative of currents and voltages of the electrical power system; and
a processing system including at least one internal analog-to-digital converter configured to convert the analog measurement signals into digital samples,
wherein the analog front-end circuitry includes,
a current measurement front end comprising, for at least one phase, a current transformer configured to generate a current sample proportional to a current flowing in a conductor of the electrical power system, offset circuitry electrically coupled to a secondary winding of the current transformer and configured to bias terminals of the secondary winding to a middle voltage point, and a transimpedance amplifier powered from a single power rail and referenced to the middle voltage point and configured to convert the current sample into a current-related voltage signal,
a voltage measurement front end comprising a plurality of phase voltage inputs configured to receive respective phase voltages Va, Vb, and Vc of the electrical power system, a reference voltage input configured to receive a reference voltage Vn associated with the electrical power system, and voltage sensing circuitry configured to generate analog voltage signals corresponding to the phase voltages Va, Vb, Vc and the reference voltage Vn, and
a middle voltage reference circuit powered from the single power rail and configured to generate the middle voltage point between a supply voltage and a ground node,
wherein the processing system is configured to,
control the at least one internal analog-to-digital converter to obtain digital samples of the current-related voltage signal and the analog voltage signals corresponding to Va, Vb, Vc, and Vn,
obtain, for each of a plurality of measurement intervals, a plurality of digital samples for at least one of the current-related voltage signal and the analog voltage signals,
generate, for each of the plurality of measurement intervals, at least one oversampled result based on the plurality of digital samples,
determine phase-differential voltages based on differences between digital samples representative of the phase voltages Va, Vb, Vc and digital samples representative of the reference voltage Vn,
and apply at least one correction factor based on calibration data stored in a memory unit to the at least one oversampled result to provide a corrected measurement value for use in computing at least one power-related quantity.

16. The electronic power meter of claim 15, wherein the offset circuitry comprises at least one diode pair connected across the secondary winding of the current transformer and configured to limit a voltage across the secondary winding.

17. The electronic power meter of claim 15, wherein the transimpedance amplifier comprises an operational amplifier having a feedback resistor connected between an output terminal and an inverting input terminal and having a non-inverting input terminal biased to the middle voltage point.

18. The electronic power meter of claim 15, wherein the at least one internal analog-to-digital converter is integrated within a microcontroller of the processing system and is configured to perform simultaneous sampling of at least one of the phase voltages and the reference voltage Vn.

19. The electronic power meter of claim 15, wherein generating the at least one oversampled result comprises averaging eight digital samples obtained for a given analog measurement signal during a corresponding one of the plurality of measurement intervals.

20. The electronic power meter of claim 15, wherein the calibration data comprises at least one offset value and at least one linearization parameter associated with the at least one internal analog-to-digital converter, and wherein applying the at least one correction factor comprises adjusting the at least one oversampled result based on the at least one offset value and the at least one linearization parameter.
